(19) United States
(12) Patent Application Publication
(10) Pub. No.: US 2001/0056560 A1
(43) Pub. Date: Dec. 27, 2001

(54) METHOD AND SYSTEM FOR MEASUREMENT BASED AUTOMATIC RETRANSMISSION REQUEST IN A RADIOCOMMUNICATION SYSTEM

(76) Inventors: FAROOQ KHAN, KISTA (SE); HAKAN OLOFSSON, STOCKHOLM (SE); ANDERS FURUSKAR, STOCKHOLM (SE); MIKAEL HOOK, SOLLENTUNA (SE)

Correspondence Address: BURNS DOANE SWECKER & MATHIS L L P, POST OFFICE BOX 1404, ALEXANDRIA, VA, 22313-1404, US

(21) Appl. No.: 09/168,064

(22) Filed: Oct. 8, 1998

(51) Int. Cl. G06F 11/00; H04L 1/00; G06F 11/30; H03M 13/00; G08C 25/00

(52) U.S. Cl. 714/746; 714/704

(57) ABSTRACT

Hybrid ARQ techniques for error handling are described. The amount of redundancy transmitted in response to a first NACK message associated with a first attempt to decode a data block is variable. The number of redundancy units transmitted (and/or requested) can be selected based on various criteria including, for example, estimated channel quality, estimated block quality, memory usage, a number of outstanding blocks, etc.

### BACKGROUND

The present invention generally relates to error handling in the field of communication systems and, more particularly, to error handling using automatic retransmission requests (ARQ) and variable redundancy in digital communication systems.

The growth of commercial communication systems and, in particular, the explosive growth of cellular radiotelephone systems, have compelled system designers to search for ways to increase system capacity without reducing communication quality beyond consumer tolerance thresholds. One technique to achieve these objectives involved changing from systems wherein analog modulation was used to impress data onto a carrier wave, to systems wherein digital modulation was used to impress the data on carrier waves.

In wireless digital communication systems, standardized air interfaces specify most of the system parameters, including modulation type, burst format, communication protocol, etc. For example, the European Telecommunication Standard Institute (ETSI) has specified a Global System for Mobile Communications (GSM) standard that uses time division multiple access (TDMA) to communicate control, voice and data information over radio frequency (RF) physical channels or links using a Gaussian Minimum Shift Keying (GMSK) modulation scheme at a symbol rate of 271 ksps. In the U.S., the Telecommunication Industry Association (TIA) has published a number of Interim Standards, such as IS-54 and IS-136, that define various versions of digital advanced mobile phone service (D-AMPS), a TDMA system that uses a differential quadrature phase shift keying (DQPSK) modulation scheme for communicating data over RF links.

TDMA systems subdivide the available frequency into one or more RF channels. The RF channels are further divided into a number of physical channels corresponding to timeslots in TDMA frames. Logical channels are formed of one or several physical channels where modulation and coding is specified. In these systems, the mobile stations communicate with a plurality of scattered base stations by transmitting and receiving bursts of digital information over uplink and downlink RF channels.

Digital communication systems employ various techniques to handle erroneously received information. Generally speaking, these techniques include those which aid a receiver to correct the erroneously received information, e.g., forward error correction (FEC) techniques, and those which enable the erroneously received information to be retransmitted to the receiver, e.g., automatic retransmission request (ARQ) techniques. FEC techniques include, for example, convolutional or block coding of the data prior to modulation. FEC coding involves representing a certain number of data bits using a certain (greater) number of code bits, thereby adding redundancy which permits correction of certain errors. Thus, it is common to refer to convolutional codes by their code rates, e.g., ½ and ⅓, wherein the lower code rates provide greater error protection but lower user bit rates for a given channel bit rate.

ARQ techniques involve analyzing received blocks of data for errors and requesting retransmission of blocks which contain errors. Consider, for example, the block mapping example illustrated in FIG. 1 for a radiocommunication system operating in accordance with the Generalized Packet Radio Service (GPRS) optimization which has been proposed as a packet data service for GSM. Therein, a logical link control (LLC) frame containing a frame header (FH), a payload of information and a frame check sequence (FCS) is mapped into a plurality of radio link control (RLC) blocks, each of which include a block header (BH), information field, and block check sequence (BCS), which can be used by a receiver to check for errors in the information field. The RLC blocks are further mapped into physical layer bursts, i.e., the radio signals which have been GMSK modulated onto the carrier wave for transmission. In this example, the information contained in each RLC block can be interleaved over four bursts (timeslots) for transmission.

When processed by a receiver, e.g., a receiver in a mobile radio telephone, each RLC block can, after demodulation, be evaluated for errors using the block check sequence and well known cyclic redundancy check techniques. If there are errors, then a request is sent back to the transmitting entity, e.g., a base station in a radiocommunication system, denoting the block to be resent using predefined ARQ protocols.

Strengths and weaknesses of these two error control schemes can be balanced by combining FEC and ARQ techniques. Such combined techniques, commonly referred to as hybrid ARQ techniques, permits correction of some received errors using the FEC coding at the receiver, with other errors requiring retransmission. Proper selection of FEC coding schemes with ARQ protocols thus results in a hybrid ARQ technique having greater reliability than a system employing a purely FEC coding scheme with greater throughput than a system employing a purely ARQ-type error handling mechanism.

An example of a hybrid ARQ scheme can be found in GPRS. The GPRS optimization provides four FEC coding schemes (three convolutional codes of different rate and one uncoded mode). After one of the four coding schemes is selected for a current LLC frame, segmentation of this frame to RLC blocks is performed. If an RLC block is found to be erroneous at the receiver (i.e., it has errors which cannot be corrected) and needs to be retransmitted, the originally selected FEC coding scheme is used for retransmission, i.e., this system employs fixed redundancy for retransmission purposes. The retransmitted block may be combined with the earlier transmitted version in a process commonly referred to as soft combining in an attempt to successfully decode the transmitted data.

Another proposed hybrid ARQ scheme, sometimes referred to as incremental redundancy or type-I hybrid ARQ, provides for additional redundant bits to be transmitted if the originally transmitted block cannot be decoded. This scheme is conceptually illustrated in FIG. 2. Therein, three decoding attempts are made by the receiver. First, the receiver attempts to decode the originally received data block (with or without redundancy). Upon failure, the receiver then receives additional redundant bits R1, which it uses in conjunction with the originally transmitted data block to attempt decoding. As a third step, the receiver obtains another block of redundant information R2, which it uses in conjunction with the originally received data block and the block of redundant bits R1 to attempt decoding for a third time. This process can be repeated until successful decoding is achieved.

One problem with the technique illustrated in FIG. 2 is the large memory requirement associated with storing the data block (and possibly additional blocks of redundant bits) until a successful decode occurs, which storage is needed since the subsequently transmitted redundancy blocks (e.g., R1 and R2) are not independently decodable. The storage requirements are multiplied by the fact that the receiver typically stores a multi-bit soft value associated with each received bit, the soft values indicating a confidence level associated with the decoding of the received bit. This problem can be partially solved by employing the technique described in the article entitled “Complementary Punctured Convolutional (CPC) Codes and their Applications” to Samir Kallel, published in IEEE Transactions on Communications, Vol. 43, No. 6, pp. 2005-2009 in June 1995. Therein, the author describes an error correction technique wherein each retransmitted block is itself independently decodable so that when memory space is unavailable previously transmitted blocks can be discarded.

A second problem encountered with the scheme of FIG. 2 is the large packet transfer delays. These large delays are introduced because, on average, several redundancy retransmissions are required before successful decoding occurs. A third problem associated with the proposed schemes is the inefficient bandwidth utilization due to a stalled ARQ window. The ARQ window is stalled because of the large number of outstanding blocks (i.e., unacknowledged blocks) at a given time.

Accordingly, it would be desirable to provide new techniques for improving ARQ schemes which reduce overhead signaling, improve the efficiency of memory utilization and minimize the number of redundancy transmissions associated with each decoding in a manner which will permit more efficient processing.

### SUMMARY

These and other drawbacks and limitations of conventional methods and systems for communicating information are overcome according to the present invention, wherein the receiver processes a received block. If the decoding is unsuccessful, a quality estimate is made on the received information. The quality estimate can be based solely on the quality of the particular block which has been erroneously received, solely based on historical data associated with channel quality or it can be some combination of the two. The quality estimate can, for example, be extracted from the soft values that are derived in the receiver. Then, based on the quality estimate, the amount of redundancy required for the successful decoding of the information block is determined. The receiver then sends a not acknowledged (NACK) message to the transmitter identifying the block to be retransmitted along with the amount of desired redundancy, whereupon the desired amount of redundancy is transmitted.

If the decoding is unsuccessful after the second attempt, then the process continues by determining a second quality estimate associated with both the originally transmitted block and the subsequently transmitted redundant bits. This second quality estimate is then used to determine a next amount of redundant information to be requested, and so on.

Measurement-based hybrid ARQ schemes according to the present invention will minimize the number of redundancy transmission steps thus reducing the packet transmission delays and the amount of memory required. This is achieved due to the reduced number of ACK/NACK loops required for successful decoding with the measurement based scheme. An exemplary implementation of the present invention provides an estimation of the amount of redundancy depending upon the quality of the received previous data block/redundancy block and/or the quality of the channel. However, other exemplary embodiments of the present invention also include cases where the amount of redundancy transmitted depends upon other factors such as the amount of memory available, data delay requirements and/or the number of outstanding (unacknowledged) blocks for a given transmission. For example, when the amount of memory is limited or delay requirements are stringent, the redundancy estimation could be scaled up in order to increase the probability of successful decoding in the next step.

### BRIEF DESCRIPTION OF THE DRAWINGS

These and other objects, features and advantages of the present invention will become more apparent upon reading from the following detailed description, taken in conjunction with the accompanying drawings, wherein:

FIG. 1 depicts information mapping in a conventional system operating in accordance with GSM;

FIG. 2 illustrates a conventional variable redundancy technique;

FIG. 3(a) is a block diagram of a GSM communication system which advantageously uses the present invention;

FIG. 3(b) is a block diagram used to describe an exemplary GPRS optimization for the GSM system of FIG. 3(a);

FIG. 4 is a flowchart illustrating a measurement-based ARQ scheme according to an exemplary embodiment of the present invention;

FIG. 5 shows a table describing an exemplary relationship between a number of redundancy units to be transmitted, a coding rate and a corresponding code;

FIG. 6 shows a format for a an ACK/NACK according to an exemplary embodiment of the present invention;

FIG. 7(a) illustrates block transmission time using a conventional incremental redundancy scheme;

FIG. 7(b) depicts an illustrative block transmission time for the same data as in FIG. 7(a) using techniques according to the present invention; and

FIG. 8 is a table illustrating the cumulative improvement in delay times using the present invention.

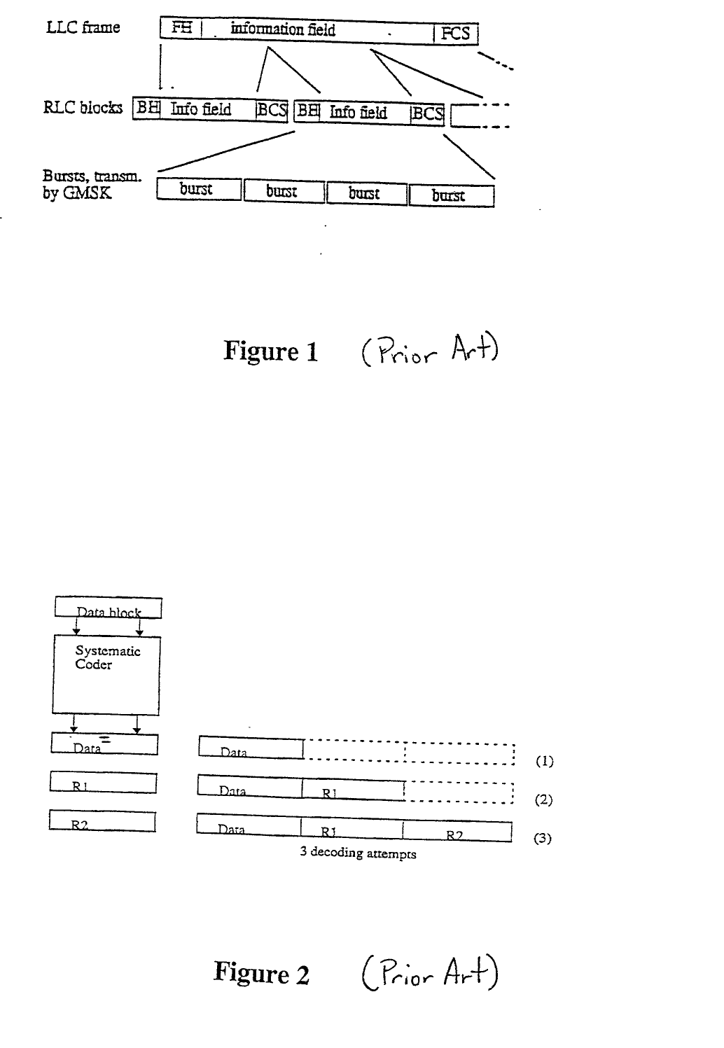

### DETAILED DESCRIPTION

The following exemplary embodiments are provided in the context of TDMA radiocommunication systems. However, those skilled in the art will appreciate that this access methodology is merely used for the purposes of illustration and that the present invention is readily applicable to all types of access methodologies including frequency division multiple access (FDMA), TDMA, code division multiple access (CDMA) and hybrids thereof.

Moreover, operation in accordance with GSM communication systems is described in European Telecommunication Standard Institute (ETSI) documents ETS 300 573, ETS 300 574 and ETS 300 578, which are hereby incorporated by reference. Therefore, the operation of the GSM system in conjunction with the proposed GPRS optimization for packet data (hereafter referred to simply as “GPRS”) is only described herein to the extent necessary for understanding the present invention. Although, the present invention is described in terms of exemplary embodiments in an enhanced GPRS system, those skilled in the art will appreciate that the present invention could be used in a wide variety of other digital communication systems, such as those based on wideband CDMA or wireless ATM, etc.

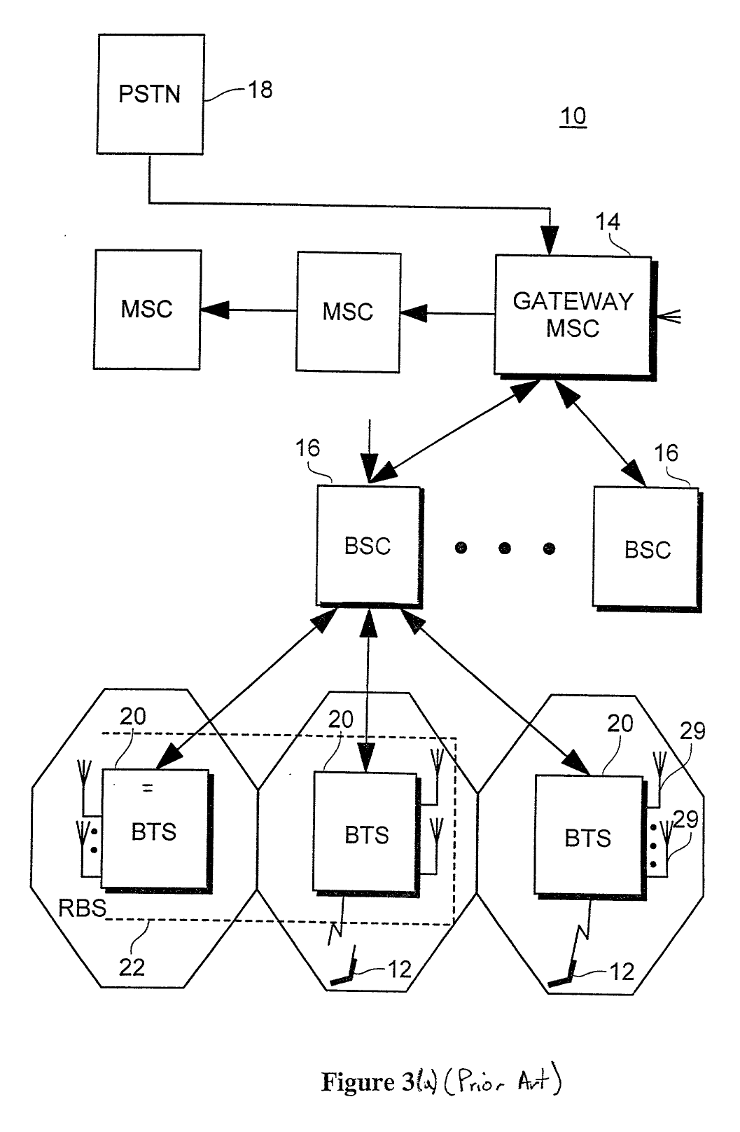

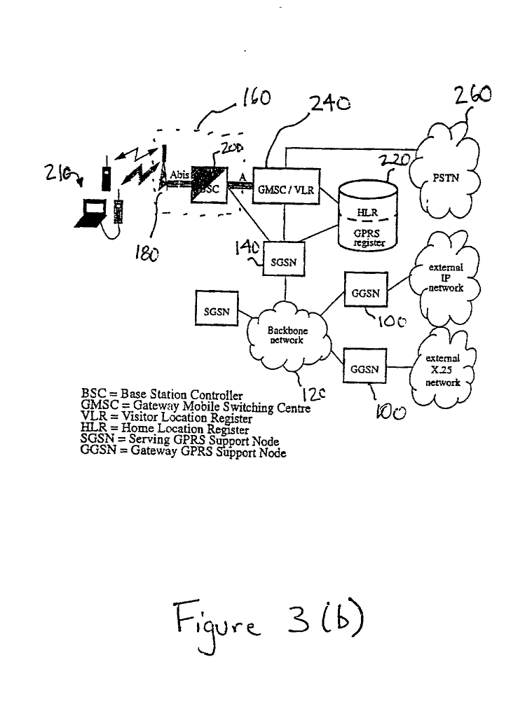

Referring to FIG. 3(a), a communication system 10 according to an exemplary GSM embodiment of the present invention is depicted. The system 10 is designed as a hierarchical network with multiple levels for managing calls. Using a set of uplink and downlink frequencies, mobile stations 12 operating within the system 10 participate in calls using time slots allocated to them on these frequencies. At an upper hierarchical level, a group of Mobile Switching Centers (MSCs) 14 are responsible for the routing of calls from an originator to a destination. In particular, these entities are responsible for setup, control and termination of calls. One of the MSCs 14, known as the gateway MSC, handles communication with a Public Switched Telephone Network (PSTN) 18, or other public and private networks.

At a lower hierarchical level, each of the MSCs 14 are connected to a group of base station controllers (BSCs) 16. Under the GSM standard, the BSC 16 communicates with a MSC 14 under a standard interface known as the A-interface, which is based on the Mobile Application Part of CCITT Signaling System No. 7.

At a still lower hierarchical level, each of the BSCs 16 controls a group of base transceiver stations (BTSs) 20. Each BTS 20 includes a number of TRXs (not shown) that use the uplink and downlink RF channels to serve a particular common geographical area, such as one or more communication cells 21. The BTSs 20 primarily provide the RF links for the transmission and reception of data bursts to and from the mobile stations 12 within their designated cell. When used to convey packet data, these channels are frequently referred to as packet data channels (PDCHs). In an exemplary embodiment, a number of BTSs 20 are incorporated into a radio base station (RBS) 22. The RBS 22 may be, for example, configured according to a family of RBS-2000 products, which products are offered by Telefonaktiebolaget LM Ericsson, the assignee of the present invention. For more details regarding exemplary mobile station 12 and RBS 22 implementations, the interested reader is referred to U.S. patent application Ser. No. 08/921,319, entitled “A Link Adaptation Method For Links using Modulation Schemes That Have Different Symbol Rates”, to Magnus Frodigh et al., the disclosure of which is expressly incorporated here by reference.

An advantage of introducing a packet data protocol in cellular systems is the ability to support high data rate transmissions and at the same time achieve a flexibility and efficient utilization of the radio frequency bandwidth over the radio interface. The concept of GPRS is designed for so-called “multislot operations” where a single user is allowed to occupy more than one transmission resource simultaneously.

An overview of the GPRS network architecture is illustrated in FIG. 3(b). Since GPRS is an optimization of GSM, many of the network nodes/entities are similar to those described above with respect to FIG. 3(a). Information packets from external networks will enter the GPRS network at a GGSN (Gateway GPRS Service Node) 100. The packet is then routed from the GGSN via a backbone network, 120, to a SGSN (Serving GPRS Support Node) 140, that is serving the area in which the addressed GPRS mobile resides. From the SGSN 140 the packets are routed to the correct BSS (Base Station System) 160, in a dedicated GPRS transmission. The BSS includes a plurality of base transceiver stations (BTS), only one of which, BTS 180, is shown and a base station controller (BSC) 200. The interface between the BTSs and the BSCs are referred to as the A-bis interface. The BSC is a GSM specific denotation and for other exemplary systems the term Radio Network Control (RNC) is used for a node having similar functionality as that of a BSC. Packets are then transmitted by the BTS 180 over the air interface to a remote unit 210 using a selected information transmission rate.

A GPRS register will hold all GPRS subscription data. The GPRS register may, or may not, be integrated with the HLR (Home Location Register) 220 of the GSM system. Subscriber data may be interchanged between the SGSN and the MSC/VLR 240 to ensure service interaction, such as restricted roaming. As mentioned above, the access network interface between the BSC 200 and MSC/VLR 240 is a standard interface known as the A-interface, which is based on the Mobile Application Part of CCITT Signaling System No. 7. The MSC/VLR 240 also provides access to the landline system via PSTN 260.

Retransmission techniques can be provided in system 10 so that a receiving entity (RBS 180 or MS 210) can request redundant bits associated with an RLC block from a transmitting entity (MS 210 or RBS 180). According to exemplary embodiments of the present invention, the amount of redundant information requested by the receiving entity and transmitted in response to the request (e.g., a not acknowledged (NACK) message) is variable.

More specifically, the receiver can evaluate the erroneously received RLC block to obtain some estimate regarding how poorly it was received, i.e., its quality. This estimate could, for example, be a measure of bit error rate (BER) or carrier-to-interference ratio (C/I). The receiver then determines the amount of redundancy to request from the transmitter based on the quality estimate for a particular, erroneously received RLC block. In the following discussion, the return of redundancy information is described in terms of redundancy units which can, of course, be any size, e.g., a block of bits, a byte or even a single bit and can be generated in a known manner using a polynomial generator. Generally speaking, the lower the quality estimate, the greater the number of redundancy units that are requested. In addition to (or as an alternative to) basing the amount of redundancy requested on the quality estimate of the erroneously received block itself, systems and methods for error handling according to exemplary embodiments of the present invention may also take into account channel quality over which the block was transmitted and over which the requested redundancy units will be transmitted. For example, the number of redundancy units requested may be based on a global quality measure such as Q=α * channel quality+(1-α) * received block quality, where α is a desired weighting value.

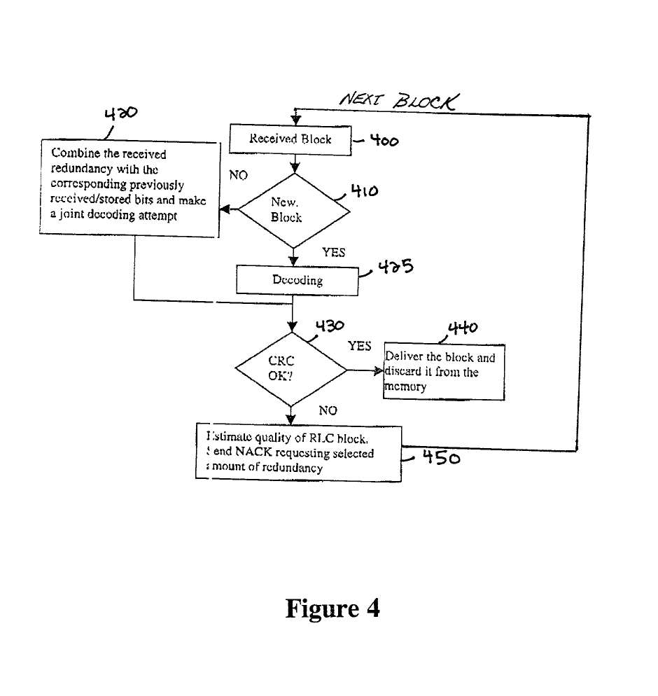

Thus, an exemplary method according to the present invention is illustrated by the flow chart of FIG. 4. Therein, at block 400, the receiver receives an RLC block which is either data, previously requested redundant bits or some combination thereof. If the RLC block contains only redundant bits associated with a previously received RLC block, then the process moves along the “NO” arrow from decision block 410 to block 420, wherein the redundant bits are combined with previously received/stored bits of a corresponding RLC block and a joint decoding attempt is made. For a more detailed discussion of how redundant bits are matched with earlier received data for joint decoding, the interested reader is referred to U.S. patent application Ser. No. 09/131,166, entitled “Method and System for Block Addressing in a Packet Data Radiocommunication System”, filed on Aug. 7, 1998 to Farooq Khan et al., the disclosure of which is expressly incorporated here by reference. Otherwise, if the received block is a new RLC block, the process moves along the “YES” path from decision block 410 to block 425 where the new block is decoded. Then the flow moves to block 430 where a cyclic redundancy check (CRC) is performed. If the CRC passes, i.e., the data is received correctly, then the process moves to block 440 wherein the block is delivered for subsequent processing, e.g., speech decoding, etc. If the CRC fails, then the flow moves to block 450 wherein an estimate of the quality of the erroneously received block is made, e.g., based on a relative BER or C/I parameter. The quality estimate (and, possibly, other factors described below) is then used to select a desired amount of redundant bits to be used in the next decoding attempt. The receiver then transmits an NACK message associated with this ( and possibly other) RLC blocks, which NACK message indicates the amount of redundancy that the receiver wishes for the transmitter to send. The flow then loops back to process the next received block.

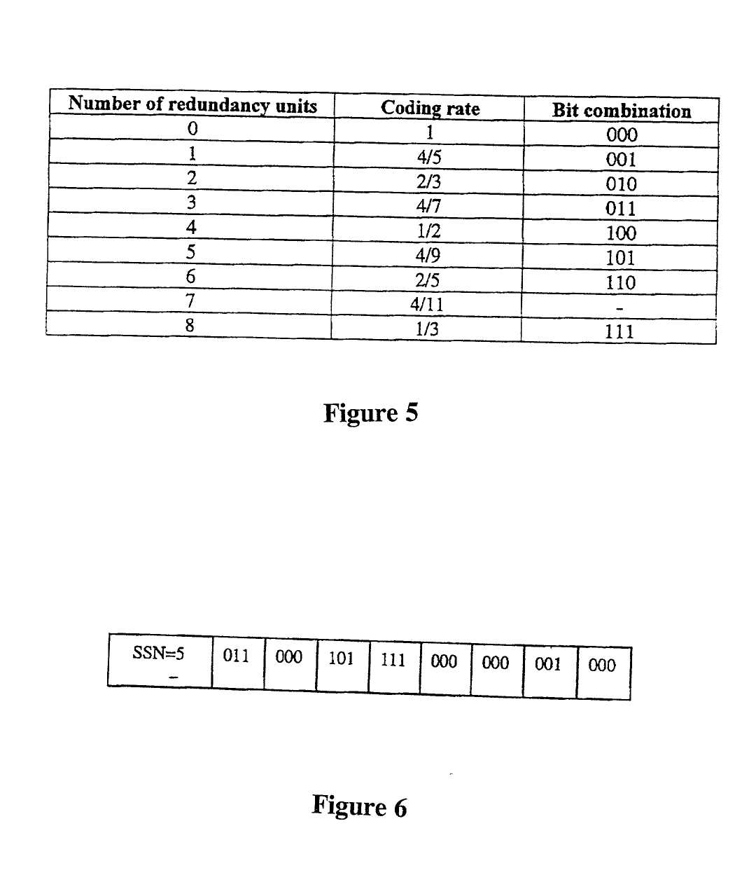

Those skilled in the art will appreciate that requesting the number of redundancy units to be transmitted can, in exemplary embodiments employing convolutional encoding, be considered as substantially equivalent to specifying a desired coding rate for a particular block that was erroneously received. For example, as illustrated in the table of FIG. 5, for an RLC block containing four “units” of data, requesting any number from 1-8 of redundancy units to be transmitted results in a different effective coding rate for the second attempt at decoding the data. Thus, for example, an erroneously received RLC block that has nonetheless relatively high quality, may result in the receiver requesting only one redundancy unit from the transmitter. A very poorly received RLC block may, on the other hand, result in the receiver requesting eight redundancy units for that specific RLC block. The particular relationship between estimated RLC block quality and number of redundancy units requested may vary from system to system and can, for example, be optimized through simulation to achieve the desired result of minimizing the number of decoding attempts per block as described below.

Once the receiver has evaluated the quality of received RLC block and selected a desired amount of redundancy, it will include this information in a report to the transmitter. Using the example of FIG. 5, each different number of redundancy units which can be transmitted may be assigned a different code or bit combination. Then, the receiver can send an acknowledged/not acknowledged (ACK/NACK) message identifying the amount of desired redundancy, if any, for each recently received RLC block. An example is provided in FIG. 6.

Therein an ACK/NACK message containing the information [(5(3), 6(0), 7(5), 0(8), 1(0), 2(0), 3(1), 4(0)] is illustrated. In the foregoing notation, “5(3)” denotes that three redundancy units are requested by the receiver for the RLC block having a sequence number of 5. For the RLC block having a sequence number of 6, the receiver has included the code 000, indicating that no redundancy information need be transmitted since that RLC block was correctly received.

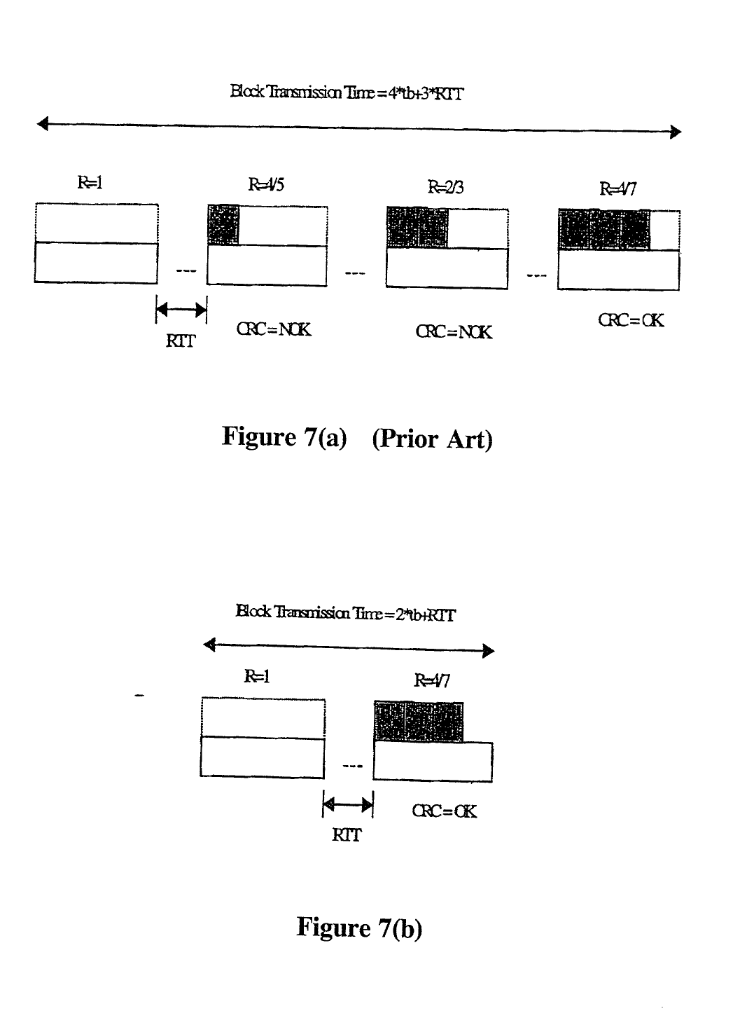

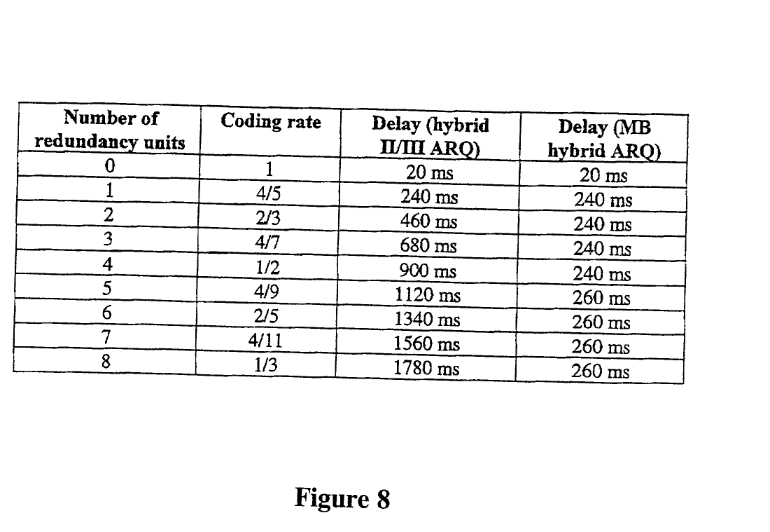

As mentioned earlier, by tailoring the amount of redundancy requested to the quality of the received block, Applicants anticipate that fewer decoding passes will be needed per block as compared with conventional techniques wherein the same amount of redundancy is transmitted for each erroneously received block. This point will be more evident upon consideration of FIGS. 7(a), 7(b) and 8.

Therein, exemplary block transfer times using the conventional incremental redundancy scheme (FIG. 7(a)) and the measurement-based variable redundancy scheme are compared. For this purely illustrative example, a block period equals 20 ms, a round trip time (RTT) between transmission of an RLC block by a transmitting entity and receipt of a corresponding ACK/NACK message by that transmitting entity is 200 ms and an erroneously received RLC block needs three units of redundant information (i.e., a coding rate of 4/7) to be properly decoded. Thus, in FIG. 7(a) it will be seen that four transmissions are required until the CRC passes for this RLC block, wherein after each failure the transmitting entity sends an additional unit of redundancy. By way of contrast, employing the present invention, the receiver is able to request three units of redundancy based on the estimated quality of this RBC block so that only two passes are needed, thereby reducing the block transfer delay from 680 ms to 240 ms, respectively. Those skilled in the art will appreciate that the actual different in delays associated with the two techniques may also vary depending upon other conditions, e.g., varying radio channel conditions. Moreover, the delay difference will increase with the number of redundancy transmission steps used in the conventional technique as illustrated by the table in FIG. 8. It will be understood that the numerical values provided in the foregoing example are merely illustrative and intended to make clearer advantages associated with the present invention.

In addition to reducing delay, exemplary embodiments of the present invention also reduce the likelihood that the ARQ window will stall and reduce memory requirements. This is because techniques according to the present invention minimize the number of outstanding blocks by ensuring a faster block decoding and delivery. By preventing a stalled ARQ window condition, more efficient bandwidth utilization is obtained since new RLC blocks cannot be transmitted during a stalled condition.

As mentioned earlier, the block of data as originally transmitted may include some redundant information, i.e., may have some level of FEC coding. This initial level of FEC coding may be determined by the transmitting entity based upon information that the transmitting entity receives regarding the channel quality. For example, a mobile station may make estimates regarding channel quality and forward those estimates to a base station. Then, the base station can use the received channel estimates to select an appropriate amount of redundancy to transmit with the payload information to the mobile station. Preferably, the base station would select an amount of redundancy which will allow the mobile station to decode the data block on its first attempt given the channel quality estimate. However, those skilled in the art will appreciate that the base station may select a greater or lesser amount of redundancy depending upon various current system factors such as those described earlier.

Although the invention has been described in detail with reference only to a few exemplary embodiments, those skilled in the art will appreciate that various modifications can be made without departing from the invention. For example, information regarding the number of redundancy units to be transmitted could be passed back to the transmitter implicitly, e.g., by sending the estimated quality of measures for each block, rather than explicitly as in the example of FIG. 6. The transmitter will then determine an appropriate number of redundancy units to return. In determining the number of redundancy units, the transmitter may take into account, in addition to the received quality measures, other factors such as resource availability, etc. Accordingly, the invention is defined only by the following claims which are intended to embrace all equivalents thereof.

What is claimed is:

1. A method for transferring information over a communication link comprising the steps of:
receiving a block of data over said communication link;
determining a quality level of at least one of said received data block and said communication link; and
requesting a quantity of additional information associated with said data block, said quantity selected based on said determined quality level.

2. The method of claim 1, wherein said step of determining further comprises the step of:
estimating a bit error rate associated with said received data block.

3. The method of claim 1, wherein said step of determining further comprises the step of:
using soft information obtained during a decoding process to determine said quality level.

4. The method of claim 1, wherein said step of requesting further comprises the step of:
transmitting a message identifying said data block and said quantity of additional information.

5. The method of claim 1, further comprising the step of:
selecting, as said quantity of additional information, a number of units of redundant information.

6. The method of claim 5, wherein said selected number of units of redundant information varies inversely relative to said determined quality level.

7. The method of claim 1, wherein said step of determining said quality level further comprises the step of:
determining said quality level based solely on said received data block.

8. The method of claim 1, wherein said step of determining said quality level further comprises the step of:
determining said quality level based solely on a quality of said communication link.

9. The method of claim 1, wherein said step of determining said quality level further comprises the step of:
determining said quality level based on a combination of quality information associated with said received block and quality information associated with said communication link.

10. The method of claim 1, further comprising the step of:
transmitting said requested quantity of additional information.

11. The method of claim 1, further comprising the step of:
transmitting a quantity of additional information which is different than said requested quantity.

12. The method of claim 11, wherein said transmitted quantity of additional information and said requested quantity of additional information differ based on at least one of: a memory usage parameter, a number of outstanding blocks and a resource availability.

13. An apparatus for transferring information over a communication link comprising:
means for receiving a block of data over said communication link;
means for determining a quality level of at least one of said received data block and said communication link; and
means for requesting a quantity of additional information associated with said data block, said quantity selected based on said determined quality level.

14. The apparatus of claim 13, wherein said means for determining further comprise:
means for estimating a bit error rate associated with said received data block.

15. The apparatus of claim 13, wherein said means for determining further comprises:
means for using soft information obtained during a decoding process to determine said quality level.

16. The apparatus of claim 13, wherein said means for requesting further comprises:
means for transmitting a message identifying said data block and said quantity of additional information.

17. The apparatus of claim 13, further comprising:
means for selecting, as said quantity of additional information, a number of units of redundant information.

18. The apparatus of claim 13, wherein said selected number of units of redundant information varies inversely relative to said determined quality level.

19. The apparatus of claim 13, wherein said means for determining said quality level further comprises:
means for determining said quality level based solely on said received data block.

20. The apparatus of claim 13, wherein said means for determining said quality level further comprises:
means for determining said quality level based solely on a quality of said communication link.

21. The apparatus of claim 13, wherein said means for determining said quality level further comprises:
means for determining said quality level based on a combination of quality information associated with said received block and quality information associated with said communication link.

22. The apparatus of claim 13, further comprising:
means for transmitting said requested quantity of additional information.

23. The apparatus of claim 13, further comprising:
means for transmitting a quantity of additional information which is different than said requested quantity.

24. The apparatus of claim 23, wherein said transmitted quantity of additional information and said requested quantity of additional information differ based on at least one of: a memory usage parameter, a number of outstanding blocks and a resource availability.

25. A method for decoding information blocks in a radiocommunication system comprising the steps of:
receiving a block of information;
decoding said block;
performing an error detection technique on said decoded sblock;
if said block is determined to have been erroneously received, then determining a quality level;
selecting, based on said quality level, a desired amount of redundant information;
transmitting a request for said desired amount of redundant information to a transmitting entity;
receiving said requested amount of redundant information; and
jointly decoding said block of information and said redundant information.

26. The method of claim 25, wherein said step of performing further comprises the step of:
performing a cyclic redundancy check (CRC) on said block of information.

27. The method of claim 25, wherein said quality level is a quality of said received block.

28. The method of claim 25, wherein said quality level is a quality of a channel over which said redundant information will be transmitted.

29. A method for communicating information between a transmitting entity and a receiving entity comprising the steps of:
estimating, at said receiving entity, a channel quality;
transmitting, by said receiving entity, an indication associated with said channel quality; and
transmitting, by said transmitting entity, a block of information plus an amount of redundancy associated with said information, wherein said amount is based on said indication.

30. A method for transferring information between a first transceiver and a second transceiver comprising the steps of:
receiving a data block at said first transceiver;
estimating a quality associated with one of said received blocks and a channel;
transmitting by said first transceiver, said estimated quality to a second transceiver;
determining, at said second transceiver, an amount of redundancy based, at least in part, on said estimated quality; and
transmitting, by said second transceiver, said amount of redundancy to said first transceiver.

31. A method for communicating information between a first transceiver and a second transceiver comprising the steps of:
receiving a data block at said first transceiver;
estimating a first quality associated with at least one of said received block and a channel;
transmitting, by said first transceiver, an indication associated with a selected amount of redundancy based on said estimated first quality;
transmitting, by said second transceiver, said selected amount of redundancy to said first transceiver;
estimating, at said first transceiver, a second quality associated with at least one of both said received block and received redundancy information and said channel quality; and
transmitting an indication of said estimated second quality to said second transceiver.
